(19) United States
(12) Patent Application Publication
(10) Pub. No.: US 2014/0167169 A1
(43) Pub. Date: Jun. 19, 2014

(54) ESD PROTECTION CIRCUIT

(71) Applicant: MACRONIX INTERNATIONAL CO., LTD., Hsin-Chu City (TW)

(72) Inventors: CHIEH WEI HE, KAOHSIUNG CITY (TW); QI AN XU, JIANGSU PROVINCE (CN); JUN JUN YU, JIANGSU PROVINCE (CN); HAN HAO, JIANGSU PROVINCE (CN)

(73) Assignee: MACRONIX INTERNATIONAL CO., LTD., HSIN-CHU CITY (TW)

(21) Appl. No.: 13/718,713

(22) Filed: Dec. 18, 2012

(51) Int. Cl. H01L 27/02

(52) U.S. Cl. CPC H01L 27/0255
USPC 257/355; 257/491

(57) ABSTRACT

An electrostatic discharge (ESD) protection circuit connecting to an input pad is configured to dissipate an ESD current. The circuit has a substrate of a first conductivity type, a first well of a second conductivity type in the substrate, and a second well of the first conductivity type in the first well. The circuit further has a diode device having a first end of the first conductivity type electrically coupled to the input pad and a second end of the second conductivity type in the second well. Moreover, the protection circuit has a first doped region of the second conductivity type in the first well electrically connecting to the input pad, and a second doped region of the first conductivity type in the substrate electrically coupled to the ground. The circuit also has a channel formed between the input pad and the second doped region to provide an ESD current discharge.

### FIELD OF THE INVENTION

The present invention relates in general to an ESD protection circuit, and more particularly to an ESD protection circuit with low current leakage.

### BACKGROUND

Protecting a device from the threat of ESD damage has been an ongoing challenge for those skilled in the art. Conventional ESD protection structures usually include a diode string with one end electrically coupled to the I/O pad and the other end electrically coupled to the ground in order to dissipate the high current passing through the circuit. Typically, the diode string is constructed to have a well with a different conductivity type to the substrate in order to accommodate both ends of the diode. Unfortunately, a parasitic BJT that is formed by one of the diode's terminals, the well, and the substrate, provides an undesirable current leakage path when the device is under normal operations, for example, a 10V bias applied on the I/O pad to perform the designed function of the circuit. The power consumption becomes one of the drawbacks to having an ESD protection circuit in a IC device.

Besides the leakage, another challenge to conventional ESD design is the reduced layout area. The increased popularity of small-sized electronic devices limits the flexibility of layouts for circuit designers. In addition to the ESD current from the I/O pad, protection for reverse ESD (or so-called negative stress) is also crucial to the device. An extra area is always reserved to insert another diode device between the ground and the I/O pad as a channel to dissipate the negative stress. However, the sacrificed area may increase the unit cost of the device since the transistor density needs to be lowered.

Therefore, it is desirable to provide ESD protection for devices by preventing current leakage during normal operations. It is also desirable to provide a channel for discharging a negative stress ESD current with minimum area required.

### SUMMARY OF THE INVENTION

The objective of the present invention is to provide an ESD protection circuit. In the ESD protection circuit, a well with a different conductivity type to the substrate in which it embeds, is added to surround a diode for dissipating the ESD current. Additionally, a doped region is formed in the well to be electrically coupled to an input pad and one end of the diode is also coupled to the input pad in order to build an electrical potential barrier to block the current leaking from the diode into the well. Furthermore, the well and the substrate form another diode to provide an additional channel to dissipate an ESD current from the ground. Therefore, the layout area required for designing a reverse diode to prevent a negative stress can be reduced.

The invention achieves the above-identified object by providing an ESD protection circuit connected to an input (or I/O) pad. The ESD circuit includes at least a first device, which may be a PNP BJT, having an emitter with a first end coupled to the input pad. The circuit may also have a second device, which is exemplary, and shown schematically as a diode. A first pole of the second device is coupled to the emitter of the first device and the pad. Moreover, a third device is also included in the protection circuit. The second device can also be a diode series, wherein a second pole is electrically coupled to ground. One pole of the third device is coupled to the pad and the other pole of the device is coupled to the ground and the third device can be a diode. The circuit can further include a fourth device with a ground-gate NMOS transistor. One end of the NMOS structure is coupled to the second pole of the second device and one end is coupled to the ground.

The invention achieves the above-identified object by providing an ESD protection circuit connected to an input (or I/O) pad. The ESD circuit includes a substrate of a first conductivity type, a first well of a second conductivity type in the substrate, and a second well of the first conductivity type in the first well. The protection circuit further includes a second well string having at least one second well, an N+ doped region in the first well coupled to the input pad, and a P+ doped region in the substrate. The P+ doped region is coupled to the ground. The diode string forms in the first well and includes a second well, a first end, and a second end, wherein the first end is electrically coupled to the pad.

### BRIEF DESCRIPTION OF THE DRAWINGS

The invention will be described according to the appended drawings in which:

FIG. 1 illustrates an effective circuitry of an ESD protection circuit;

FIG. 2 depicts the semiconductor structure of an ESD protection circuit;

FIG. 3 depicts the semiconductor structure of an ESD protection circuit according to one embodiment;

FIG. 4 depicts the semiconductor structure of an ESD protection circuit according to one embodiment;

FIG. 5 depicts the representative cross-sectional drawing of an ESD protection circuit according to one embodiment;

FIG. 6 depicts the representative cross-sectional drawing of an ESD protection circuit according to one embodiment with an impedance compared to FIG. 5; and

FIG. 7 depicts the representative cross-sectional drawing of an ESD protection circuit according to one embodiment.

### DETAILED DESCRIPTION OF THE INVENTION

The embodiments of the present invention are described more fully hereinafter with reference to the accompanying drawings, which form a part hereof, and which show, by way of illustration, specific exemplary embodiments by which the invention may be practiced. This invention may, however, be embodied in many different forms and should not be construed as limited to the embodiments set forth herein; rather, these embodiments are provided so that this disclosure will be thorough and complete, and will fully convey the scope of the invention to those skilled in the art. As used herein, the term “or” is an inclusive “or” operator, and is equivalent to the term “and/or,” unless the context clearly dictates otherwise. In addition, throughout the specification, the meaning of “a,” “an,” and “the” include plural references. The term “coupled” implies that the elements may be directly connected together or may be coupled through one or more intervening elements.

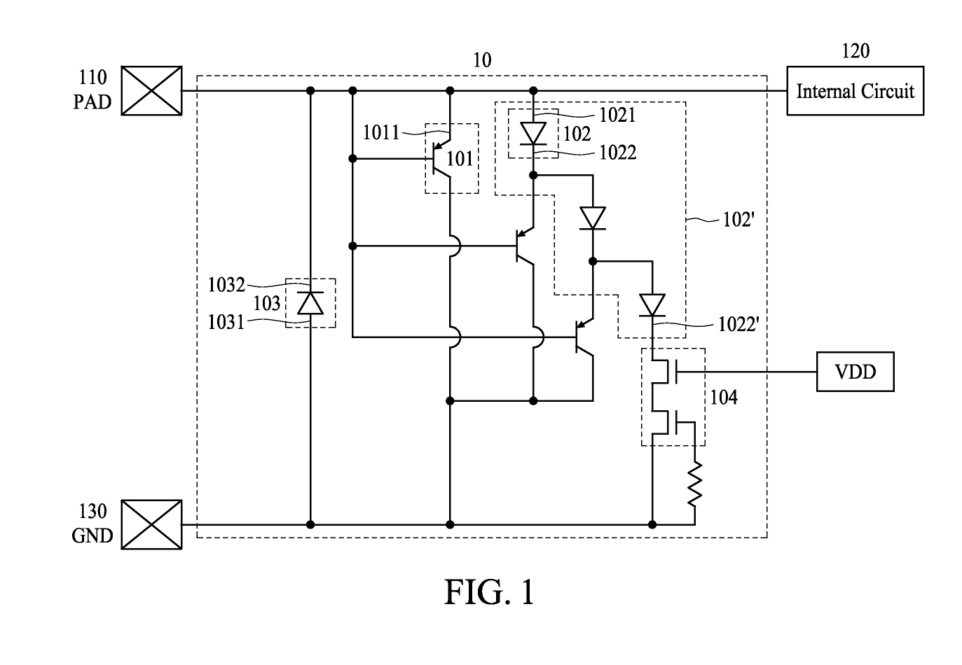

FIG. 1 illustrates an effective circuitry of an ESD protection circuit 10 according to an embodiment of the present disclosure. The circuit 10 may be incorporated into a semiconductor circuit and electrically coupled to an input (or I/O) pad 110, an internal circuit 120 and the ground 130. Therefore the internal circuit 120 can be protected from ESD damage or other electric shock. The circuit 10 includes at least a first device 101, which may be but is not limited to a PNP BJT, having an emitter electrically coupled to the input pad 110. The circuit 10 may also have a second device 102, which is exemplary, and shown schematically as a diode. A first pole 1021 of the second device 102 is electrically coupled to the emitter of the first device 101 and the pad 110. The second device 102 can also be a diode series 102′ as shown in FIG. 1, wherein a second pole 1022′ is electrically coupled to the ground. Moreover, a third device 103, is also included in the protection circuit 10. One pole 1032 of the third device 103 is coupled to the pad 110 and the other pole 1031 of the device 103 is coupled to the ground. Optionally, the third device 103 can be a diode. The circuit 10 can further have a fourth device 104 having a ground-gate NMOS structure. One end of the NMOS structure is coupled to the second pole 1022 of the second device 102 and one end is coupled to the ground 130. In the present embodiment, if an ESD current is introduced into the input pad 110, the current is discharged from the second device 102 to the fourth device 104, and then to the ground. Conversely, if an ESD current is introduced from the ground, the current is discharged from the ground pad 130 to the third device 103, and then to the input pad 110. Therefore, the present embodiment provides at least two main discharge paths for an ESD damage current. One for the ESD current introduced from the pad 110, and another for the ESD current introduced from the ground pad, with the second mode usually known as negative stress ESD. Another purpose of the present embodiment is to reduce leakage when the internal circuit is under normal operation. As in normal operation, a bias, such as 10.5V, may be applied on the pad 110 to drive the internal circuit 120, preferably avoiding the leakage through the ESD protection circuit 10. The first device 101 may be one of the major leakage paths if it is inappropriately designed. In the present embodiment, as illustrated in FIG. 1, the first device 101 is designed to be in cut-off mode (for a PNP BJT, both junctions are under reverse bias or zero bias) when the bias is applied on the input pad 110. Therefore, the conducting path from the pad 110 to the ground 130 is cutoff by the first device 101 to prohibit any flow leaking through.

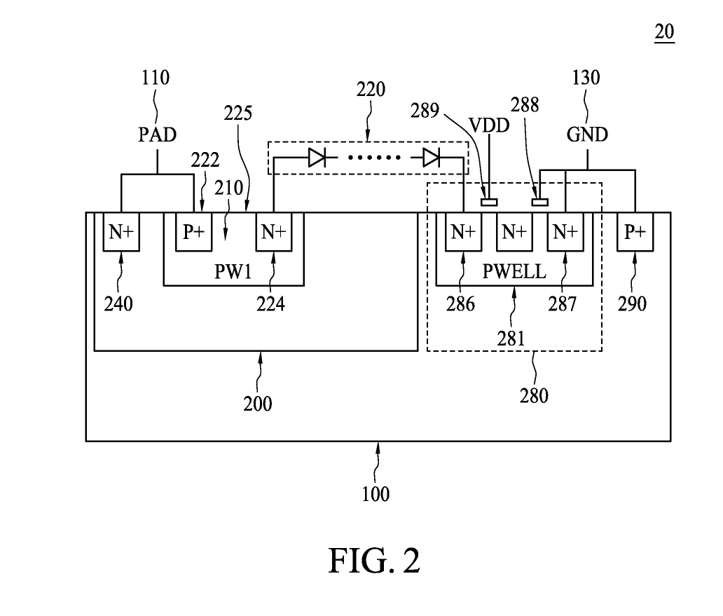

Another embodiment according to the present disclosure of a semiconductor structure of an ESD protection circuit 20 is depicted in FIG. 2. The ESD protection circuit 20 is electrically coupled to an input pad 110, such as an I/O pad or a high voltage input pad. The ESD protection circuit 20 includes a substrate 100 of a first conductivity type, a first well 200 of a second conductivity type in the substrate 100, and a second well 210 of the first conductivity type in the first well 200. In the embodiment, the first conductivity type is a P-type, the first well 200 is an N-well and the second well 210 is a P-well. The protection circuit 20 further includes a diode string 220 having at least one diode device 225, an N+ first doped region 240 in the first well 200 coupled to the input pad 110, and a second doped region 290, can be a P-type doped region, in the substrate 100. The P+ doped region 290 is coupled to the ground 130. In the embodiment, the substrate 100 is P-typed and the diode device 225 is the first diode of the diode string 220. The diode string 220 forms in the first well 200 and includes a second well 210, a first end 222, and a second end 224, wherein the first end 222 is electrically coupled to the pad 110. In the embodiment, the first end 222 is a P+ region and the second end 224 is an N+ region.

There is another diode which is the junction formed at the contact interface of the substrate 100 and the first well 200, wherein the diode is the reversal to the diode string 220 in view of the pad 110 (The diode series 220 is P-N, and the diode formed herein is N-P).

The present embodiment provides at least two different channels for dissipating the ESD current introduced from different directions. When the discharging current is introduced into the circuit from the pad 110, also called a forward ESD in the present disclosure, the high current travels through each diode in the diode string 220 and then to the ground 130. On the other hand, when the discharging current is introduced from the ground 130, or so-called negative stress mode (NS mode) in the present disclosure, the high current may dissipate through the substrate 100, the N+ doped region 240 and then to the input pad 110. By embedding the first well 200 in the different conductivity type substrate 100 to surround the diode 220, it becomes unnecessary to reserve an extra layout area to have a diode for discharging NS mode ESD current.

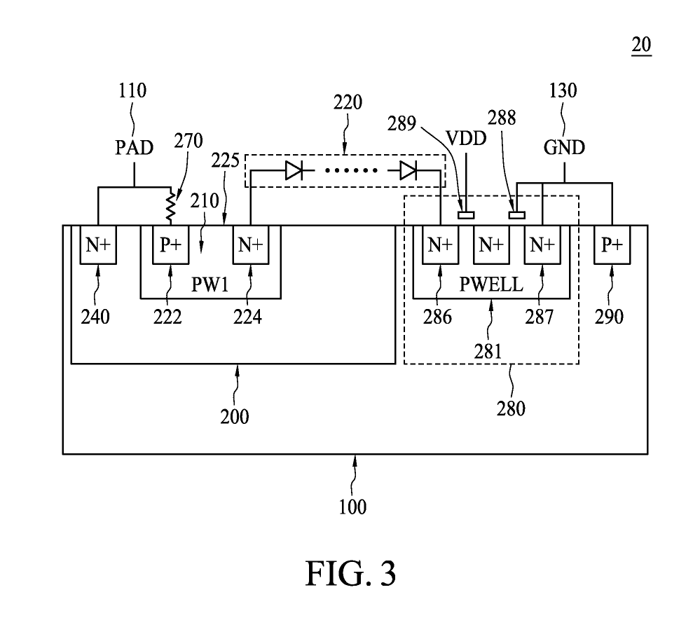

Another feature of the present disclosure is to minimize the current leakage from the diode series 220 to the ground 130 when the internal circuit is under normal operations. During the normal operations, a bias voltage is applied on the pad 110 in order to drive the internal circuit. Ideally, the ESD protection circuit 20 coupled to the pad 110 should be always turned off to avoid any power consumption. Unfortunately, the first end 222 of the diode 220, the first well 200, and the substrate 100 may form a channel for leakage. Thus, with the N+ doped region 240 coupled to the pad 110, the electrical potential difference on the interface between the P well 210 and the N well 200 may form a barrier to the leakage current from the P well 210 flowing into N well 200. For the first diode 225 in the diode series, the electrical potential in the P well 210 may be equivalent to the electrical potential in the N well 200. But for the second and other subsequent diodes, since each diode causes a higher voltage drop than in the N well 200, the higher potential barriers formed outside the diodes can block the leakage. Moreover, by further adjusting the doping concentration or profile of the wells, the embodiment may provide a higher potential barrier at the interface to block the leakage current. Another embodiment as illustrated in FIG. 3 shows an impedance 270 located between the first end 222 of the diode 225 and the pad 110 in order to provide a larger voltage drop on the diode side to enhance the leakage reduction.

Referring back to FIG. 2, the embodiment can further have a MOS structure 280 disposed between the ground 130 and the diode string 220. The structure includes a third well 281 of the first conductivity type in the substrate 100, a third doped region 286 of the second conductivity type in the third well 281, a fourth doped region 287 of the second conductivity type in the third well 281, and a gate 288 between the third and fourth doped regions, wherein the third doped region 286 is electrically coupled to the second end 224 of the diode 225 and the fourth doped region 287 is electrically coupled to the second doped region 290. The gate 288 is electrically coupled to the ground 130 and may be designed to be a common ground with the fourth doped region 287. The MOS structure 280 can further have a second gate 289 disposed between the gate 288 and the third doped region 286. Optionally, the second gate 289 is coupled to a Vdd as needed.

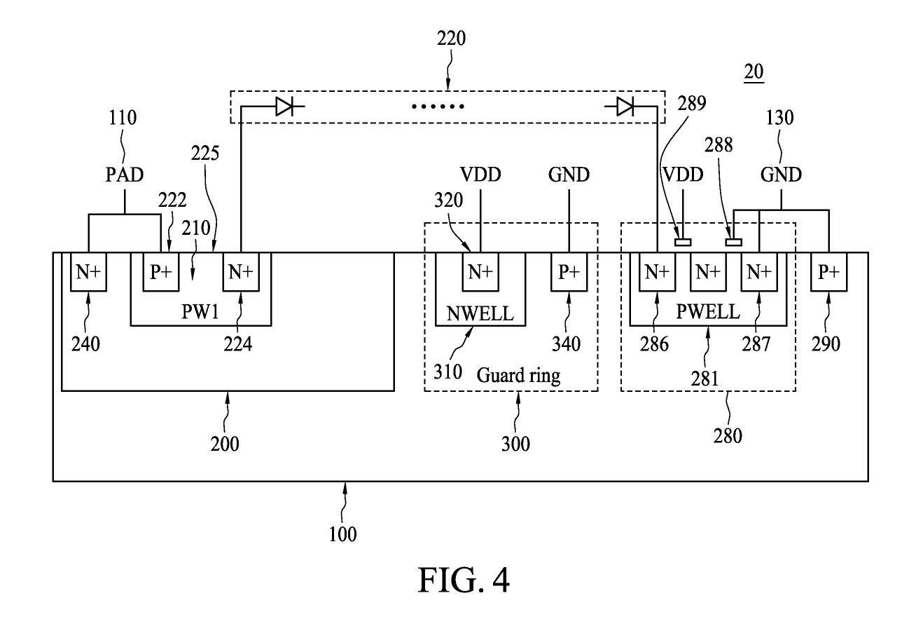

FIG. 4 depicts an embodiment with a guard ring structure 300 between the diode string 220 and the second doped region 290, or the guard ring structure 300 can be arranged between the diode string 220 and the MOS structure 280. The guard ring structure 300 has a fourth well 310, a fifth doped region 320 in the fourth well 310, and a sixth doped region 340 in the substrate 100. In the embodiment, the fourth well 310 is an N well and the fifth doped region 320 is an N+ doped region. The fifth doped region 320 can be electrically coupled to a Vdd in order to capture electrons flowing in the substrate. The sixth doped region 340 can be a P+ doped region and electrically coupled to the ground 130, such that the positive carriers, such as holes flowing in the substrate 100 are captured by the sixth doped region 340.

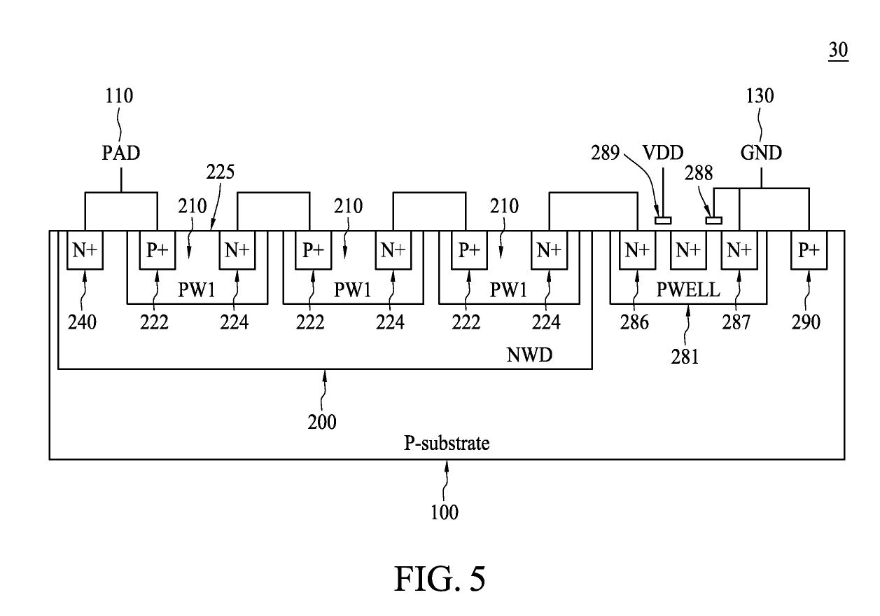

Another embodiment is illustrated in FIG. 5. An ESD protection circuit 30 includes at least a substrate 100 of a first conductivity type, a first well 200 of a second conductivity type in the substrate 100, and a second well 210 of the first conductivity type in the first well 200. In the embodiment, the first conductivity type is a P-type and the second conductivity type is an N-type. There is also a P-type first doped region 222 and an N-type second doped region 224 in the second well 210, wherein the first doped region 222 is electrically coupled to the pad 110. Furthermore, an N+ third doped region 240 is in the first well 200 and a P+ fourth doped region 290 is in the substrate 100. More specifically, the N+ third doped region 240 is electrically coupled to the input pad 110, and the P+ fourth doped region 290 is electrically coupled to the ground 130. There may be more than one second well 210 in the first well 200 formed sequentially after the first second well 210. Each second well 210 has its corresponding and identical P-type first doped region 222 and N-type second doped region 224 and are connected in a serial mode as shown in FIG. 5. For an embodiment with only a single second well 210, the N-type second doped region 224 is coupled to the ground 130. For a string pattern, the N-type second doped region 224 in the rightmost second well 210 is electrically coupled to the ground 130.

The second well 210, the first doped region 222 and the second doped region 224 together form a first diode 225, wherein the first doped region 222 is a first end of the first diode 225 and the second doped region 224 is a second end of the first diode 225. The P+ fourth doped region 290, the substrate 100, the first well 200 and the N+ third doped region 240 together effectively form a second diode, wherein the P+ fourth doped region 290 is the first end of the second diode and the N+ third doped region 240 is the second end of the second diode.

The embodiment provides two dissipation channels for introducing an ESD current. One channel is from the pad 110, to the first doped region 222, to the second well 210, then to the second doped region 224, and finally to the ground 130. Another channel is from the fourth doped region 290, to the substrate 100, to the first well 200, then to the N+ third doped region 240, and finally to the pad 110. The second channel is also called a negative stress channel in order to distinguish from the ESD current introduced from the pad 110.

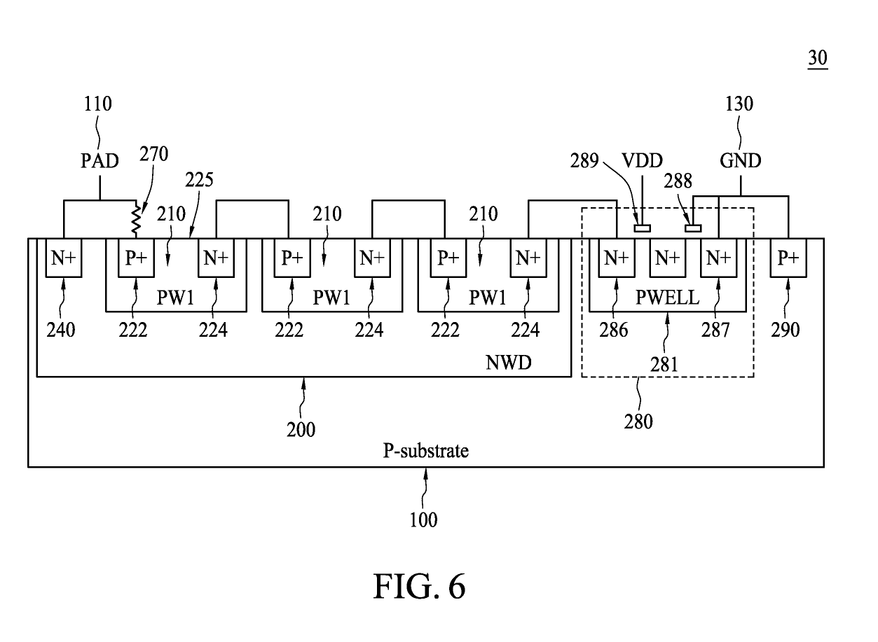

Since the first well 200 is designed to surround the second well 210, and both the N+ third doped region 240 and the first doped region 222 are commonly electrically coupled to the same pad 110, when a bias is applied on the pad 110, a forward bias is avoidable between the junction formed by the first well 200 and the second well 210. The leakage from the second well 210 to the first well 200 thus can be dramatically reduced. In another embodiment, as shown in FIG. 6, an impedance 270 can be added between the first doped region 222 and the pad 110, such that the voltage gap at the interface between the first well 200 and the second well 210 is increased. Therefore a higher electrical potential barrier is formed to block leakage current from the second well 210 flowing into the first well 200.

The embodiment can further have a third well 281 of a P-type in the substrate 100, a fifth doped region 286 of an N-type in the third well 281, and a sixth doped region 287 of the N-type in the third well 281. The fifth doped region 286 is electrically coupled to the second doped region 224 and the sixth doped region 287 is electrically coupled to the fourth doped region 290. There is also a gate 288 between the fifth and the sixth doped region, wherein the gate 288 is electrically coupled to the ground 130. There may be another gate 289 between the gate 288 and the fifth doped region 286, wherein the gate 289 is electrically coupled to a Vdd.

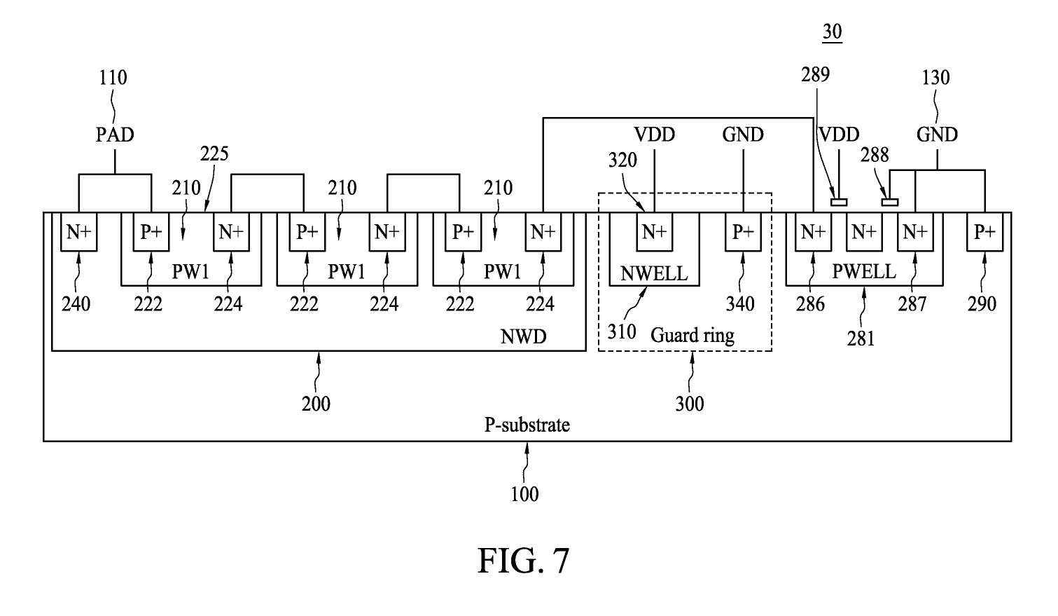

FIG. 7 is another embodiment which further has a fourth well 310 of the N-type in the substrate 100 and the fourth well 310 is located between the N+ second doped region 224 and the P+ fourth doped region 290, a seventh doped region 320 of the N-type in the fourth well 310, and an eighth doped region 340 of the P-type in the substrate 100 located between the N+ second doped region 224 and the P+ fourth doped region 290, or between the second doped region 224 and the fifth doped region 286.

The methods and features of this invention have been sufficiently described in the above examples and descriptions. It should be understood that any modifications or changes without departing from the spirit of the invention are intended to be covered in the protection scope of the invention.

What is claimed is:

1. An electrostatic discharge (ESD) protection circuit connecting to an input pad, wherein the ESD protection circuit comprises:
a substrate of a first conductivity type;
a first well of a second conductivity type in the substrate;
a second well of the first conductivity type in the first well;
a first doped region of the first conductivity type in the second well and electrically coupled to the input pad;
to a second doped region of the second conductivity type in the second well;
a third doped region of the second conductivity type in the first well and electrically coupled to the input pad; and
a fourth doped region of the first conductivity type in the substrate.

2. The ESD protection circuit according to claim 1, wherein ESD current is discharged substantially through a channel between the fourth doped region and the input pad

3. The ESD protection circuit according to claim 1, wherein a higher electrical potential is allowed to form in the first well than that formed in the second well.

4. The ESD protection circuit according to claim 2 further comprising a first diode in the second well, wherein the first doped region is a first end of the diode and the second doped region is a second end of the diode.

5. The ESD protection circuit according to claim 4, wherein ESD current is discharged starting sequentially from the input pad, the first doped region, the second doped region, and finally to the ground.

6. The ESD protection circuit according to claim 2, wherein ESD current is discharged starting sequentially from the fourth doped region, the substrate, the first well, and then to the third doped region.

7. The ESD protection circuit according to claim 6 further comprising a second diode, wherein the fourth doped region is the first end of the second diode and the third doped region is the second end of the second diode, and the ESD current is discharged from the first end to the second end.

8. The ESD protection circuit according to claim 1, further comprising:
a third well of the first conductivity type in the substrate;
a fifth doped region of the second conductivity type in the third well;
a sixth doped region of the second conductivity type in the third well;
a gate is between the fifth and the sixth doped regions;
a fourth well of the second conductivity type in the substrate located between the second doped region and the fourth doped region; and
a seventh doped region of the second conductivity type in the fourth well, wherein the fifth doped region is electrically coupled to the second doped region and the sixth doped region is electrically coupled to the fourth doped region.

9. The ESD protection circuit according to claim 1, further comprising an eighth doped region of the first conductivity type in the substrate located between the second doped region and the fourth doped region.

10. The ESD protection circuit according to claim 1, further comprising an impedance between the input pad and the first doped region.

11. An ESD protection circuit connecting to an input pad, wherein the ESD protection circuit comprises:
a substrate of a first conductivity type;
a first well of a second conductivity type in the substrate;
a second well of the first conductivity type in the first well;
a diode device in the first well, and comprising a first end of the first conductivity type and a second end of the second conductivity type, wherein the first end is electrically coupled to the input pad;
a first doped region of the second conductivity type in the first well electrically coupled to the input pad; and
a second doped region of the first conductivity type in the substrate, electrically coupled to the ground.

12. The ESD protection circuit according to claim 11, wherein a channel between the input pad and the second doped region provides a path for discharging ESD current

13. The ESD protection circuit according to claim 11, wherein a higher electrical potential is allowed to form in the first well than that formed in the second well.

14. The ESD protection circuit according to claim 11, wherein the channel for ESD current substantially discharges sequentially from the input pad, the diode device, and finally to the ground.

15. The ESD protection circuit according to claim 11, wherein the channel for ESD current substantially discharges sequentially from the second doped region, the substrate, the first well, the first doped region and then to the input pad.

16. The ESD protection circuit according to claim 15, wherein the channel comprises a second diode.

17. The ESD protection circuit according to claim 11, further comprising:
a third well of the first conductivity type in the substrate;
a third doped region of the second conductivity type in the third well;
a fourth doped region of the second conductivity type in the third well, wherein the third doped region is electrically coupled to the second end of the diode device and the fourth doped region is electrically coupled to the second doped region; and
a gate is between the third and the fourth doped regions.

18. The ESD protection circuit according to claim 11, further comprising an NMOS structure between the diode device and the second doped region.

19. The ESD protection circuit according to claim 13, further comprising an impedance between the input pad and the first end of the diode device.

20. The ESD protection circuit according to claim 13, further comprising a guard ring structure between the diode device and the second doped region, wherein the guard ring structure comprises a fourth well, a fifth doped region in the fourth well, and a sixth doped region in the substrate.
